(19) United States
(12) Patent Application Publication
(10) Pub. No.: US 2005/0224255 A1
(43) Pub. Date: Oct. 13, 2005

(54) Plastic injected part with a plastic-coated printed circuit board, which can be equipped with components

(76) Inventor: Frank Becherer, Haslach (DE)

Correspondence Address: NATH & ASSOCIATES, 1030 15th STREET, NW, 6TH FLOOR, WASHINGTON, DC, 20005, US

(21) Appl. No.: 10/820,156

(22) Filed: Apr. 8, 2004

(51) Int. Cl. H05K 1/00

(52) U.S. Cl. 174/258

(57) ABSTRACT

The invention relates to a printed circuit board, with at least one contact element for connecting a mating contact, where the contact element is secured to the circuit board; and with a plastic layer which is applied to at least one side of the circuit board, where the contact element runs from the circuit board through plastic layer to project from this plastic layer to connect the mating contact. The invention also relates to a plastic injected part exhibiting this kind of plastic-coated circuit board, and to a process for the production of this kind of circuit board and plastic injected part.

### AREA OF INVENTION

The invention relates to a printed circuit board, a plastic injected part with a printed circuit board, and a process for their manufacture.

### BACKGROUND OF THE INVENTION

For sensors, e.g., vibration sensors and liquid level meters, a housing is positioned on the actual sensor element, and the housing contains electronic components for the control and/or evaluation of sensor signals. The electronic components usually rest on a printed circuit board, which exhibits contact elements for connecting a mating contact. The mating contact may lead to other components within this arrangement, or may lead to an external arrangement. It is important that the electronic components are tightly sealed, i.e., they must be sealed mainly against liquids and dust.

Known to the prior art is a printed circuit board with one or more contact elements for connecting a mating contact, where the contact element is attached to the printed circuit board. To provide a certain degree of protection it is also known to enclose the printed circuit boards with a so-called “hotmelt” sealing; here the applied plastic layer is thermally stable only up to 80° C. and exhibits neither high chemical nor mechanical strengths. Before the coating is applied the contact elements are secured to the printed circuit board or to a corresponding conductor material. This can be done, e.g., by pressing into position the penetrating contact elements or by gluing the penetrating contact elements into position, when such contact elements are required, e.g., for adapting a plug used by the customer as the mating contact. This circuit board is positioned inside the housing and serves to connect electronic components used in the signal evaluation for, e.g., a liquid level meter; here the electronic components are again contained in the housing.

A goal of the invention is to improve a printed circuit board exhibiting contact elements and a plastic layer with respect to durability and protection against external influences.

Another goal of the invention is to produce a plastic injected part with this kind of printed circuit board in a simple manner, and at the same time to provide an improved and especially durable protection against external influences.

A further goal consists is specifying a process that produces this kind of printed circuit board, or this kind of plastic injected part, as simply as possible.

The goal of the invention is achieved with a printed circuit board, or with a base exhibiting at least one contact element for connecting a mating contact, where the contact element is secured to the printed circuit board; and with a plastic layer, which is applied to at least one side of the base or the printed circuit board, while the contact element runs from the base through the plastic layer to project from this plastic layer in order to connect the mating contact.

The goal is also achieved in a plastic injected part with a base, or with a printed circuit board, that exhibits at least one contact element for connecting a mating contact, where the contact element is secured to the base, or to the printed circuit board; and with a plastic layer which is applied to one side of the base or printed circuit board, while the contact element runs from the base or printed circuit board through the plastic layer and projects from this plastic layer to connect the mating contact.

As to the process, the goal is achieved with a process for the partial coating of a base, or printed circuit board, exhibiting a contact element, where plastic is used for the coating and the contact element is soldered to the base or printed circuit board, whereupon the base, or printed circuit board, is coated with the plastic in such a way that the contact element runs from the base or circuit board through the plastic and projects from the plastic, or from the surface of the plastic, to connect the mating contact.

This arrangement or procedure can be elaborated in a number of highly preferred embodiments.

The plastic layer can be advantageously applied to the base on one or both sides. Especially preferred is a plastic layer that employs as its plastic a thermoplastic material with a melting point greater than 80° C., particularly greater than 100° C., while a thermoplastic material with a melting point greater than 350° C. is highly preferred, since it makes possible a thermally stable and lasting protection with advantageous plastic materials. The plastic layer will advantageously consist of a thermoplastic material with an injection temperature between about 250° C. and 410° C., particularly between 370° C. and 410° C., so that it is possible to solder at least one contact element to the circuit board by means of a high-temperature solder, in combination with spraying a plastic layer of the described type.

Preferred is a printed circuit board for which the contact element is soldered to the circuit board, or is soldered into a through-passage in the circuit board, since this provides a particularly simple means of attachment, which additionally provides good stability against bending or axial displacement. It is much preferred if the contact element is soldered to the circuit board with a high-temperature solder, particularly a high-temperature soft solder with a melting point greater than 200° C., particularly greater than 230° C. This makes it possible to subsequently spray the circuit board and the solder with a thermoplastic material which exhibits a melting temperature above 200° C., or even above 350° C., and optionally exhibits an injection temperature lower than the melting temperature of the high temperature solder.

Especially for coating with a thermoplastic material, it is advantageous to employ a circuit board of epoxy resin fiberglass laminate with an interlaced resin system.

Conductors or conductor strips positioned on the surface of the base serve to connect in conventional fashion at least one contact element to the other contact element, or to other electrical or electronic components. It is advantageous if the plastic layer covers this conductor and an adjacent surface area of the circuit board. However, the plastic layer must not cover the entire surface of the circuit board, but should ideally cover essential or all electronic components and conductors positioned on the outside surface of the circuit board.

Particularly favored are embodiments in which the circuit board or the base exhibits a through-passage into which the contact element is soldered; here a plastic layer is applied to the two opposite surfaces of the circuit board in the area of the through-passage. The bilateral, or bilateral and simultaneous, spraying of the plastic layer makes it possible to avoid damage to the solder in the area of the through-passage, especially when the plastic layer is applied or sprayed at high pressure.

### BRIEF DESCRIPTION OF THE DRAWING

In the following, an exemplary embodiment will be explained in greater detail on the basis of the drawing, which shows:

FIG. 1 a lateral sectional view of a printed circuit board with inserted contact elements, where the circuit board is partially coated with plastic;

FIG. 2 a top view of the arrangement shown in FIG. 1, in partial section;

FIG. 3 a perspective view of a housing part with a circuit board sprayed with plastic, where the plastic is simultaneously used to form a housing wall.

### DETAILED DESCRIPTION OF THE AN EXEMPLARY EMBODIMENT OF THE INVENTION

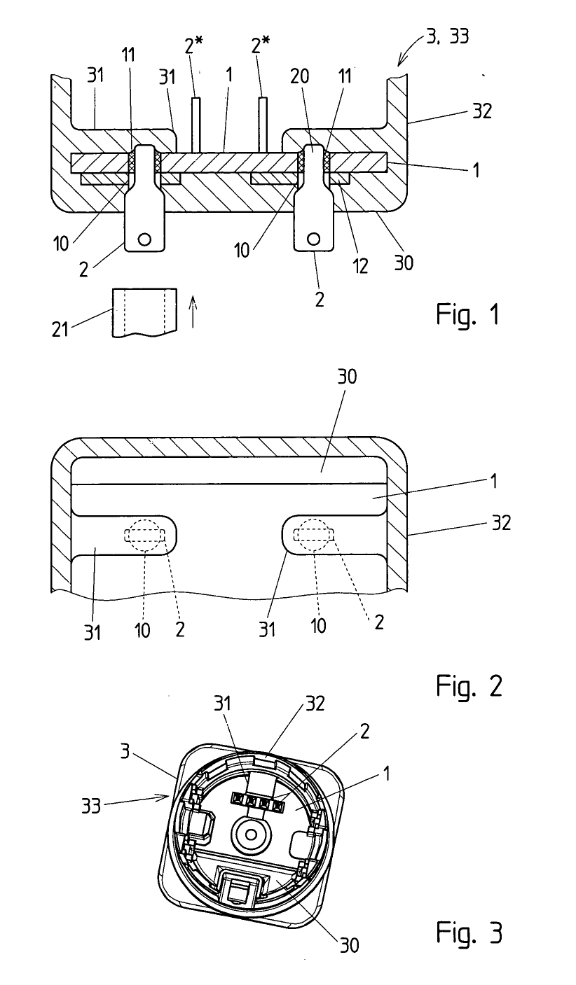

As can seen in FIGS. 1-3, contact elements 2 are attached to a printed circuit board 1. The contact elements 2 are each guided by means of a front-end terminal section 20 through a through-passage 10 in the circuit board or the base material 1. The contact elements 2 are secured by being soldered into the through-passage 10 with the solder 11. The solder 11 partially protrudes into the through-passage 10 or protrudes entirely through the latter to reach the other side of the circuit board 1. A high-temperature solder will ideally be employed as a solder.

The contact elements 2 serve as contact pins for connecting a mating contact 21, for example, a mating contact 21 in the form of a bushing positioned on the contact element 2. In order to connect electronic components connected to the mating contact 21 to other electronic components, the contact elements 2 are connected with the solder 11 to a conductor strip 12 act as conductor; the conductor strip 12 is positioned and secured to the surface of the circuit board 1 in conventional fashion. Electronic components that are positioned directly on the circuit board 1 can be attached to the conductor strip 12 and can be coated, if so desired. In the depicted exemplary embodiment other contact elements 2* are attached to the conductor strip 12. These other contact elements 2* serve in turn as contact pins for the connection of corresponding mating contacts.

The arrangement consisting of the circuit board 1, or the base, and the contact elements 2, 2* attached thereto is at least partially coated with plastic. In the depicted embodiment the plastic is applied as a downward-facing plastic layer on an initial lateral area of the circuit board 1, and this lateral area of the circuit board 1 is completely covered by the downward-facing plastic layer. In addition, an upward-facing plastic layer 31 is applied or sprayed section-wise to the opposite side of the circuit board 1. As depicted, the upward-facing plastic layer 31 covers areas of the circuit board where electric components are located, such as the contact elements 2 and the through-passages 10 leading to the opposite side of the circuit board 1.

In order to form a housing 33, plastic protrudes laterally away from the plastic with which the circuit board 1 is coated, to form a side wall 32. With this kind of arrangement a housing 33 is created in order to contain electronic components; the electronic components are received within the space formed by the circuit board 1 and the side wall 32. Such electronic components are connected by means of the mating contacts 21, which are connected to the contact elements 2. The plastic injected part created in this way thus creates a housing 33, and all electronic components, including the circuit board 1, are completely enclosed in plastic 3.

To make it possible to connect the mating contacts 21 to the contact elements 2, 2*, the contact elements 2, 2* extend laterally from the circuit board 1 to a point such that the terminal sections of the contact elements 2, 2* protrude from the plastic 3, 30, 31 and are free to be connected. In accordance with the invention process, consequently, after the contact elements 2, 2* are secured—specifically, after they are soldered to the circuit board 1—the plastic 3 is sprayed in such a way that the ends of the contact elements 2, 2* facing away from the circuit board 1 project out of the corresponding plastic layer 30, 31 without having a plastic coating.

In a highly preferred embodiment the plastic 3 is sprayed onto the side of the circuit board 1 which faces the space bordered by the lateral wall 30, but only in areas in which electronic components, contact elements 2, and/or through-passages 10 are located. In the process, it is advantageous to spray out the plastic layer 31, 30 in the area of the through-passages 10 not only bilaterally but simultaneously, in order to avoid damage to the solder 11 in the area of the through-passage 10, when spraying is performed at high pressure.

Thermoplastic material is the preferred plastic to be employed, both in order to provide a particularly good seal against liquids and dust and so that a material that is robust with respect to mechanical influences can be used for the housing 33. In initial tests the plastic employed was polyetherimide (PEI). Naturally a different plastic can be used, particularly from this class, for example, PSU, PES, PPSU, PPS, etc. All of these plastics are thermoplastics with particularly advantageous properties. The melting temperature for the highly preferred plastic will ideally be between 370° C. and 410° C., depending on the design of the structural component, i.e., the thickness and dimensions of the housing wall 32 and the geometry of the housing. However, other plastics with higher or lower melting temperatures can also be used. For the preferred plastic PEI the injection temperature is 370° C.-410° C. As compared to the hotmelt process, which operates with a low pressure in the range of 2-40×10⁵ and a melt temperature of about 200° C., the preferred process calls for the plastic to be sprayed at pressures of up to 1500×10⁵.

Because of the high pressures used in spraying, areas of the circuit board 1 that have soldering points, and particularly those involving solder 11, can be sprayed on both sides simultaneously in the area of through-passages 10, i.e., both from the upper and lower side of the circuit board 1, so as to avoid damage to the soldering points caused by the high spraying pressure.

A circuit board material that has a high resistance to temperature is preferred in order to permit work at these high temperatures. Epoxide fiberglass laminate has proven to be advantageous, particularly one with an interlaced resin system and with a glass transition temperature greater than 150° C.

A high-temperature solder will ideally be employed due to the very high temperatures of the plastic melt when the plastic is sprayed on. Preferred is a high-temperature soft solder with a melting temperature greater than 200° C., particularly greater than 230° C. or 235° C. for the highly preferred plastic. Due to its short period of contact with the hot melt and a rapid cooling that occurs within seconds, the solder is not melted, or at least is not completely melted, although the plastic melt is considerably hotter.

When other materials are used, the materials of the remaining components must have appropriate corresponding values.

Semiconductor components which cannot be completely coated due to the high temperatures of the plastic melts during spraying can be advantageously positioned on areas of the circuit board 1 that are not coated with plastic. However, contact elements 2, 2*, the conductor 12, and the solder 11 in particular can be completely coated due to their sufficient thermal stability.

In this way, a plastic injected part can be produced as a housing 33 for the sealed reception of electronic components. After the electronic components are inserted, the housing can be tightly sealed with an appropriate lid or through extended spraying and the formation of an additional wall of plastic. With the use of a thermoplastic plastic material and the spraying of the circuit board and of contact elements projecting from the plastic on both the inside and the outside, a housing 33 is produced that satisfies heavy mechanical requirements. The contact elements are protected against bending or axial displacement relative to the wall of the housing. Furthermore, the housing provides a casing that is sealed against liquid and dust for the interior and its electronic components. In this design, an advantageous feature rests in the fact that adhesives and sealers are not used, inasmuch as these would produce problems of durability upon insertion of the housing in conjunction with, e.g., a liquid level meter. In addition, the simple procedural method enables a cost-effective production of the plastic injected part with its coated circuit board.

1. A printed circuit board with
at least one contact element for connecting a mating contact, where the contact element is secured to the circuit board, and
a plastic layer, which is applied to at least one side of the circuit board,
where the contact element runs from the circuit board through the plastic layer and projects from this plastic layer to connect the mating contact.

2. A printed circuit board according to claim 1, in which the plastic layer is applied to one or both sides of the circuit board.

3. A printed circuit board according to claim 1, in which the plastic layer is a thermoplastic material with a melting point between 250° C. and 450° C., preferably between 350° C. and 410° C.

4. A printed circuit board according to claim 3, in which the plastic layer is thermoplastic material with a melting point between 350° C. and 410° C.

5. A printed circuit board according to claim 1, in which the contact element is soldered onto the circuit board.

6. A printed circuit board according to claim 1, in which the contact element is soldered to the circuit board with a high-temperature solder having a melting temperature greater than 200° C., particularly greater than 230° C.

7. A printed circuit board according to claim 3, in which the contact element is soldered to the circuit board with a high-temperature solder having a melting temperature greater than 200° C., particularly greater than 230° C.

8. A printed circuit board according to claim 1, in which the circuit board is made of a material having a thermal strength greater than 100° C., particularly greater than 150° C.

9. A printed circuit board according to claim 1, in which the circuit board consists of an epoxide fiberglass laminate with an interlaced resin system.

10. A printed circuit board according to claim 1, in which at least one conductor is positioned on the surface of the circuit board and the plastic layer covers the conductor and an adjacent surface area of the circuit board.

11. A printed circuit board according to claim 7, in which at least one conductor is positioned on the surface of the circuit board and the plastic layer covers the conductor and an adjacent surface area of the circuit board.

12. A printed circuit board according to claim 1, in which the circuit board exhibits a through-passage to which the contact element is soldered, and in which circuit board the plastic layer is applied to the two opposite surfaces of the circuit board in the area of the through-passage.

13. A printed circuit board according to claim 11, in which the circuit board exhibits a through-passage to which the contact element is soldered, and in which circuit board the plastic layer is applied to the two opposite surfaces of the circuit board in the area of the through-passage.

14. A printed circuit board according to claim 1,
in which the plastic layer is applied to one or both sides of the circuit board,
in which the plastic layer is a thermoplastic material with a melting point greater than 80° C., particularly greater than 35.0° C.,
in which the contact element is soldered to the circuit board
in which the circuit board consists of an epoxide fiberglass laminate with an interlaced resin system, and
in which at least one conductor is positioned on the surface of the circuit board and the plastic layer covers the conductor and an adjacent surface area of the circuit board.

15. A plastic injected part with
a printed circuit board that exhibits at least one contact element for connecting a mating contact, where the contact element is secured to the circuit board, and
a plastic layer, which is applied to at least one side of the circuit board,
where the contact element runs from the circuit board through the plastic layer and projects from this plastic layer to connect the mating contact.

16. A plastic injected part according to claim 15, in which the plastic extends from the plastic layer outward and laterally as the housing wall of a housing, and the plastic layer and the housing wall are produced from the same material.

17. A plastic injected part according to claim 15, in which
the plastic layer is applied to one or both sides of the circuit board,
in which the plastic layer is a thermoplastic material with a melting point greater than 80° C., particularly greater than 350° C.,
in which the contact element is soldered to the circuit board,
in which the circuit board consists of an epoxide fiberglass laminate with an interlaced resin system, and
in which at least one conductor is positioned on the surface of the circuit board and the plastic layer covers the conductor and an adjacent surface area of the circuit board.

18. A process for at least partial coating with plastic of a printed circuit board which exhibits at least one contact element, where in the process
the contact element is soldered onto the circuit board, and thereupon
the circuit board is coated with the plastic in such a way that the contact element runs from the circuit board through the plastic and projects from the plastic in order to connect a mating contact.

19. A process according to claim 18, in which the contact element is soldered into a through-passage in the circuit board, and the plastic is simultaneously sprayed as a plastic layer onto the two opposite surfaces of the circuit board in the vicinity of the through-passage.

20. A process according to claim 18, in which
the plastic used is a thermoplastic material with a melting temperature greater than 80° C., particularly higher than 100° C., and particularly higher than 350° C.,
a high-temperature solder with a melting temperature greater than 200° C., particularly greater than 235° C., is used for soldering the contact element, and
a circuit board is used whose material has a thermal stability greater than 150° C.
